(19) United States
(12) Patent Application Publication
(10) Pub. No.: US 2008/0157327 A1
(43) Pub. Date: Jul. 3, 2008

(54) PACKAGE ON PACKAGE STRUCTURE FOR SEMICONDUCTOR DEVICES AND METHOD OF THE SAME

(75) Inventor: Wen-Kun Yang, Hsin-Chu City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/933,703

(22) Filed: Nov. 1, 2007

Related U.S. Application Data
(63) Continuation-in-part of application No. 11/648,688, filed on Jan. 3, 2007.
Application No. 11/648,688 is a continuation-in-part of application No. 11/694,719, filed on Mar. 30, 2007.

(51) Int. Cl. H01L 23/02; H01L 21/00

(52) U.S. Cl. 257/686; 438/109; 257/E23.18

(57) ABSTRACT

A package on package structure for semiconductor devices comprises at least one first level package having at least first level semiconductor die therein, wherein the package having first level contact pads formed on a first upper and lower surfaces of the first level package, the first level package having a first level upper build up layers and/or a first level lower build up layer to couple to bonding pads of the first level semiconductor die to contact first level pads on the both upper and lower surfaces of the first level package; a second level package having at least one second semiconductor die contained therein, wherein the second level package has a second level contact pads on a second upper and lower surfaces of the second level package, and conductive connecting through holes; wherein the second level package have a second level upper build up layer and/or second level lower build up layer to couple second level bonding pads of the second semiconductor die to contact second level pads and the conductive connecting through holes on the upper and lower surface of the second level package, conductive through holes being coupled to the first level pads of upper and lower surfaces of the first level package and the second level pads of upper and lower surface of the second level package; and adhesion materials attached on lower surface of the first level package and the upper surface of the second level package.

### RELATED APPLICATIONS

The present application is a continuation-in-part (CIP) application of a pending U.S. application, Ser. No. 11/648,688, entitled “Wafer Level Package with Die Receiving Through-Hole and Method of the Same”, and filed on Jan. 3, 2007, and a pending U.S. application Ser. No. 11/694,719, entitled “Semiconductor Device Package with Die Receiving Through-hole and Dual Build-up Layers over Both Side-surfaces for WLP and Method of the Same”, and filed on Mar. 30, 2007, said applications incorporated herein by reference in their entirety.

### BACKGROUND OF THE INVENTION

1. Field of Invention

This invention relates to a semiconductor package, and more particularly to package on package for semiconductor devices.

2. Description of the Prior Art

Integrated circuit (IC) dice or “chips” are small, generally rectangular IC devices cut from a semiconductor wafer, such as a silicon wafer, on which multiple ICs have been fabricated. Traditionally, bare IC dice are packaged to protect them from corrosion by enclosing them in die packages. Such packages work well to protect IC dice, but they can be more bulky than desirable for certain multi-chip applications requiring compact die packaging. Improvements in IC packages are driven by industry demands for increased thermal and electrical performance and decreased size and cost of manufacture. In the field of semiconductor devices, the device density is increased and the device dimension is reduced, continuously. The demand for the packaging or interconnecting techniques in such high density devices is also increased to fit the situation mentioned above. The formation of the solder bumps may be carried out by using a solder composite material. Flip-chip technology is well known in the art for electrically connecting a die to a mounting substrate such as a printed wiring board. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip. In general, array packaging such as Ball Grid Array (BGA) packages provide a high density of interconnects relative to the surface area of the package. Typical BGA packages include a convoluted signal path, giving rise to high impedance and an inefficient thermal path which results in poor thermal dissipation performance. With increasing package density, the spreading of heat generated by the device is increasingly important. In order to meet packaging requirements for newer generations of electronic products, efforts have been expended to create reliable, cost-effective, small, and high-performance packages. Such requirements are, for example, reductions in electrical signal propagation delays, reductions in overall component area, and broader latitude in input/output (I/O) connection pad placement.

Recently, integrated circuit (chip) packaging technology is becoming a limiting factor for the development in packaged integrated circuits of higher performance. Due to the assembly package in miniature, MCM (multi-chips module) package is commonly used in the assembly package and electronic devices. Usually, the MCM package mainly comprises at least two chips encapsulated therein so as to upgrade the electrical performance of package.

U.S. Patent Publication No. 20050161833 discloses a multi-chip package as shown in FIG. 6. In the semiconductor device, via holes are formed around a chip buried in a package, one end of a conductor filled in the via-hole is covered with a pad portion exposed to the outside, and a wiring layer connected to the other end of the conductor is formed. The portion (pad portion) of the wiring layer which corresponds to the conductor is exposed from a protective film, or an external connection terminal is bonded to the top of the pad portion. Electrode terminals of the chip are connected to the wiring layer, and the opposite surface of the chip is exposed to the outside. The semiconductor devices 406 (FIG. 6) has a stacked structure in which semiconductor devices 106 are stacked in three layers to be modularized, respectively. In each of the semiconductor device 406, two vertically adjacent semiconductor devices 10 are electrically connected to each other via the top-and-bottom connecting pads (pad portions 236) of one semiconductor device and the external connection terminals (solder bumps 266) of the other, and bonded together using underfill resin 416 filled in the space between both devices. Moreover, the packages is stacked in a multilayered manner as needed by using the pad portions 236 and 24P6 respectively exposed from both surfaces of the package. A solder resist layer 25 is formed to cover the wiring layer and the resin layer.

It is because that the conventional designs include too many stacked dielectric layers and sealed compound, and the thermal dissipation is very poor, thereby decreasing the performance of the devices. The mechanical property of the dielectric layers is not “elastic/softness”, it therefore leads to the CTE mismatching issue; It lacks of the stress releasing buffer layers contained therein. Therefore, the scheme is not reliable during thermal cycle and the operation of the package.

Therefore, the present invention provides a package on package structure to overcome the aforementioned problem and also provide the better device performance.

### SUMMARY OF THE INVENTION

An object of the present invention is to provide a semiconductor device package (chip assembly) with a chip and a conductive trace that provides a low cost, high performance and high reliability package.

A further object of the present invention is to provide a PoP (Package on Package) structure for semiconductor devices.

Another object of the present invention is to provide a convenient, cost-effective method for manufacturing a semiconductor PoP.

In one aspect, a package on package structure for semiconductor devices comprises at least one first level package having at least a first level semiconductor die therein, wherein the package having first level contact pads formed on a first upper and lower surfaces of the first level package, the first level package having a first level upper build up layers and/or a first level lower build up layer to couple to bonding pads of the first level semiconductor die to contact first level pads on the both upper and lower surfaces of the first level package; a second level package having at least one second semiconductor die contained therein, wherein the second level package has a second level contact pads on a second upper and lower surfaces of the second level package, and conductive connecting through holes; wherein the second level package have a second level upper build up layer and/or second level lower build up layer to couple second level bonding pads of the second semiconductor die to contact second level pads and the conductive connecting through holes on the upper and lower surface of the second level package, the first level conductive through holes being coupled to the first level pads of upper and lower surfaces of the first level package and the second level pads of upper and/or lower surface of the second level package; and adhesion materials attached on lower surface of the first level package and the upper surface of the second level package.

The dimension of the first semiconductor package is identical to the second semiconductor package, alternatively, the dimension of the first semiconductor die is larger than the one of the second semiconductor die. The structure further comprises an isolation base formed over the first level package. The isolation base is formed of epoxy, FR4, FR5, PI or BT. The structure isolation base includes glass fiber contained therein. Solder balls/bumps are formed under the second level package. The materials of the soldering balls/bumps include lead-free compositions. The number of the conductive connecting through holes of the second level package is more than the one of the first level package. It may be at least one passive component is soldered on the upper surface of the first level package. The first, second level upper and lower build up layers include multiple conductive lines. The core paste is formed adjacent to the first and second semiconductor die. Dummy balls/bumps are provided for mechanical supporting to avoid damage from external force.

### BRIEF DESCRIPTION OF THE DRAWINGS

FIG. 1 is a cross-sectional view showing a semiconductor chip assembly in accordance with an embodiment of the present invention.

FIG. 2 is a cross-sectional view showing a semiconductor chip assembly in accordance with an embodiment of the present invention.

FIG. 3 illustrates a cross-sectional view showing a semiconductor chip assembly in accordance with an embodiment of the present invention.

FIG. 4 illustrates a cross-sectional view showing a semiconductor chip assembly in accordance with an embodiment of the present invention.

FIG. 5 (including FIGS. 5a-5c) illustrates a cross-sectional view showing a semiconductor chip assembly in accordance with a further embodiment of the present invention.

FIG. 6 illustrates a cross-sectional view showing a semiconductor chip assembly in accordance with prior art.

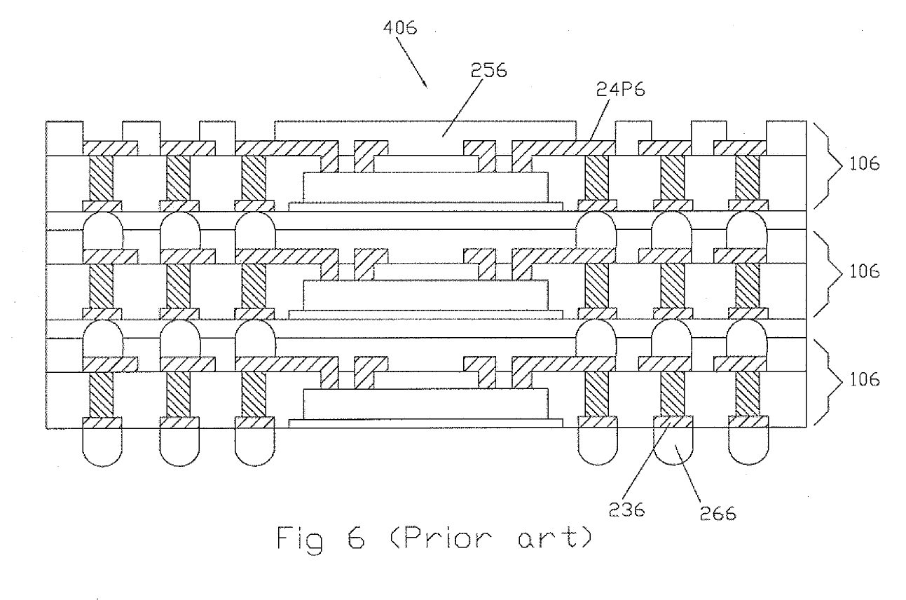

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying claims.

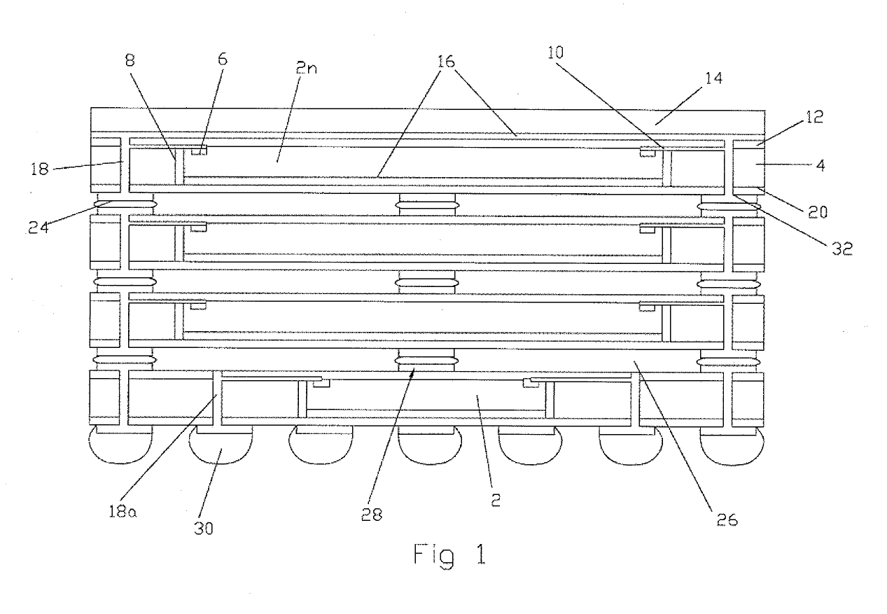

The present invention discloses a semiconductor device multi-package structure. The present invention provide a semiconductor chip assembly which includes chip, conductive trace and metal inter-connecting as shown in FIGS. 1-5. The major components and the structure of each individual package are almost identical. The embodiment will be described by using the most upper package for illustration.

The individual package includes a chip 2n which is surrounded by core material 4 having interconnecting through-hole 18 penetrating through the core material 4. Surrounding material 8 is formed between the sidewall of the chip 2n and the core material 4. The interconnecting through-hole 18 is coupled to the bonding pads 6 of the chip 2n by redistribution layer (RDL) 10. An upper build-up layer (BUL) 12 is formed over the chip 2n, the core material 4 and the RDL 10 inside. A lower BUL 20 is formed on the lower surface as well. Adhesive material 16 is coated under the chip 2n and the over the upper BUL 12 for adhesion. It could have the elastic properties to absorb the stress generated by thermal. Contact pads 32 are formed under the lower BUL 20 and aligned to the interconnecting through-holes 18, respectively. The contact metal pads 32 could be Cu/Ni/Au pads or other metal pads. The stacked build-up scheme is formed over the die (chip) 2n and the core paste (material) 2n which is formed adjacent to the die 2n for adhesion and protection. RDL (re-distribution layer) 10 is formed within the build-up layer 12.

An isolation base 14 is formed over the adhesive material 16 which is stacked over the upper build-up layer 12. For example, the isolation base 14 is composed of epoxy FR4/FR5, PI, BT, preferably, it is PI or BT base with fiber glass formed therein. In one case, the isolation base 14 includes the adhesive layer 16 formed on the lower surface. The RDL 10 is formed by an electroplating, plating or etching method. The copper (and/or nickel) electroplating operation continues until the copper layer has the desired thickness. Conductive layers extend out of the area for receiving chip. It refers to fan-out scheme. The core materials 4 encapsulated the die 2n. It can be formed by resin, compound, silicon rubber, FR5, BT or epoxy.

The lower individual packages are similar to the upper package. The lower level package does not include the isolation base 14. It includes contact pads 32 formed over the upper BUL 12. The lower contact pad of n-level package is coupled to the upper contact pads of the (n-1) level package via the solder metal inter-connecting 24 or conductive connecting through holes.

In the embodiment, at least three columns of the contact pad/solder metal inter-connecting/contact pad structure. One of the sandwich structures can be used as mechanical supporter 28. Air gap 26 is generated between two adjacent level packages to offer better thermal dissipation. Alternatively, the die 1 may be different type from other level package. It could be memory, flash, passive compounds etc. The bottom level package further includes solder bumps 30 coupled to the lower contact pads 32.

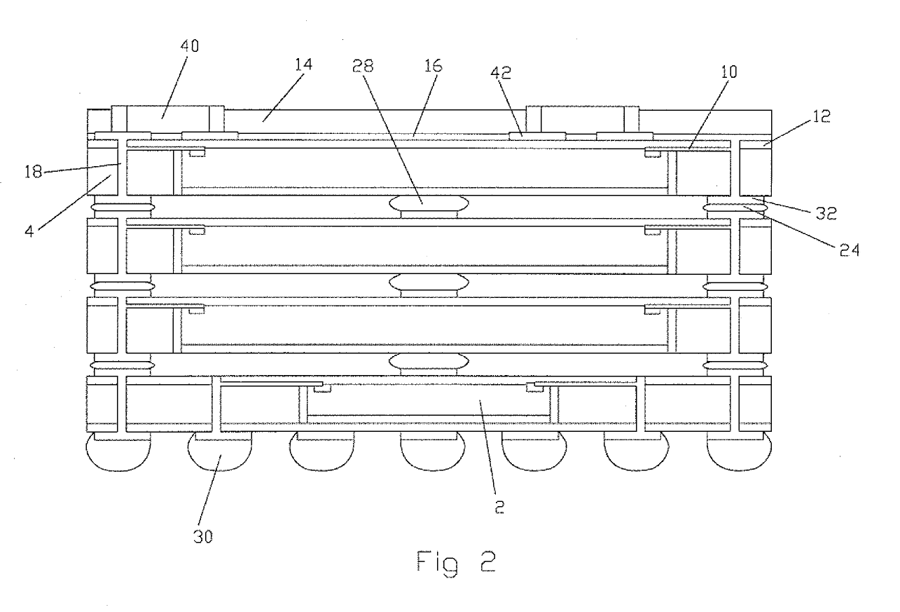

In FIG. 2 shows alternative embodiment of the present invention. Most of the structure is similar to the embodiment of above, except the upper level package structure. Please refer to FIG. 2, the package further includes a through-hole) within the isolation base 14 for receiving the passive compounds 40.

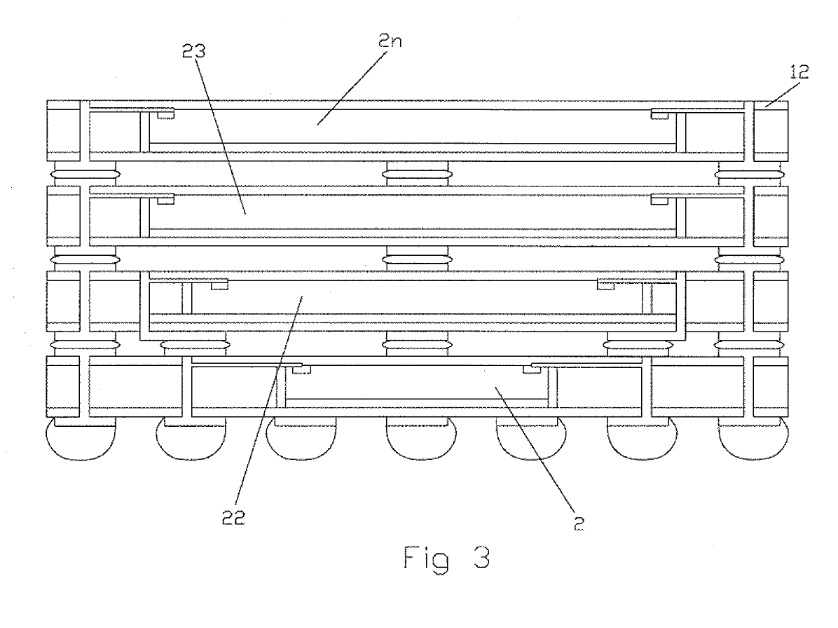

Alternatively, the isolation base is removed as shown in FIG. 3. The die size is decreased from top level to low level, subsequently. The smaller the chip is, the larger the core material is. Under the scheme, the core area of the bottom level package is the largest. It may strength the mechanical support to carry higher level package.

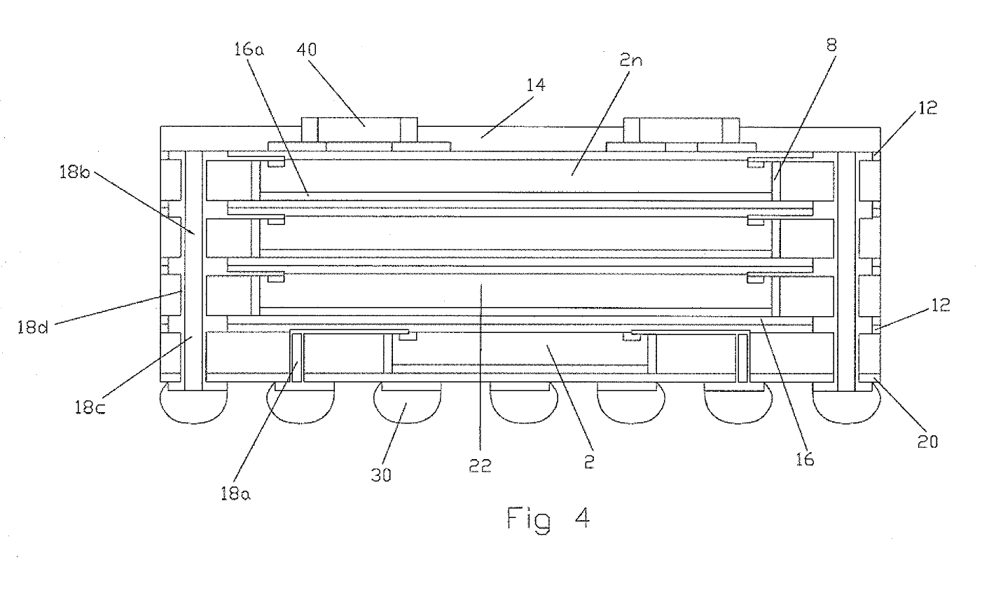

FIG. 4 illustrates another embodiment, it is similar to the second embodiment. The passive compounds 40 are formed on the adhesive material 16a. In order to form an all-level through-hole 18b (as first level inter-connecting through holes) that penetrates all levels of the packages. Conductive material 18d is coated on the surface of the all-level through-hole 18b and filling material 18c is re-filled within the all-level through-hole 18b. Comparing with all-level through-hole 18b, the inter-connecting through-hole 18a is single level through hole.

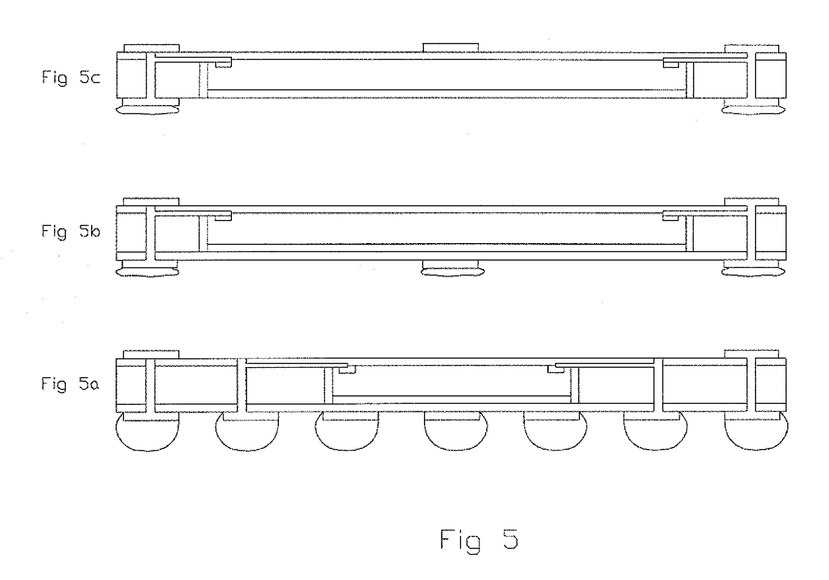

FIG. 5a-5c show upper level, mediate level and lower level package of the present invention. The upper level package includes single side BUL, while mediate and lower package include double side BULS.

The Package on Package is configured with stacking structure. Panel stacking process can be applied by using soldering metal inter-connecting or by drilling through hole, followed by forming conductive interconnecting. The panel level final testing is adaptable for each panel structure, and the panel level packaging process with fan-out structure can be applied for each panel. Repairable structure is offered and it maybe repaired by de-soldering process. The passive components are stacking on top by SMT process. Side-by-side package and package stacking are possible. The present invention offers better reliability due to same CTE (using the same core materials—BT or FR5) in each package and PCB.

A method of forming an interconnecting structure for a semiconductor die assembly, comprises the steps of:

preparing a first level substrate (the materials of the substrate is preferably BT or FR5) having first die through holes window and a first conductive connecting through holes;

embedding the at least one first die into the first level die through holes window of the first level substrate by attaching materials in the surrounding gap and under the at least one first die;

forming first level build up layers on first upper and/or lower surfaces of the at least one first die and the first level substrate to couple first level bonding pads of the at least one first die to first solder metal pads of the first level build up layers through first level conductive connecting through holes;

preparing a second level substrate (the materials of the substrate is preferably BT or FR5) having a second level die through holes window and a second conductive connecting through holes;

embedding at least second die into the second level die through holes windows of the second level by attaching materials in the surrounding gap and under the at least one second die;

forming second level build up layers on second upper and/or lower surfaces of the second die and the second level substrate to couple second level bonding pads of the second die to second solder metal pads of the second level build up layers second level through conductive connecting through holes;

printing the soldering paste on the second solder metal pads of second upper surface of the second level package; it maybe also print the soldering paste (or solder balls) on the first solder metal pads of first lower surface of the first level package to form solder bumps thereon;

mounting the first lower surface of the first level package onto soldering pastes with fine alignment mounting system;

re-flowing the soldering paste to form inter-connecting.

The method further comprises a step of sawing panels from scribe lines to separate the “PoP” package and forming RDL (within build up layers) over the first and second level packages by laminated copper foil, sputtered metal, E-plated Cu/Ni/Au.

The another method also includes the steps of forming the inter-connecting of package on package: aligning and stacking the first and second level packages (panel form) by adhesion materials; further comprising mechanical drilling the inter-connecting through holes from the first contact metal pads of first level package penetrate the core materials to second contact metal pads of second level package (also penetrate the core material of second level substrate); filling the conductive materials (can be by e-plating Cu/Ni/Au) to form inter-connecting the each contact metal pads together. Some portions of the second contact metal pads of second level package are inter-connecting together with first contact metal pads of first level package, and the other portion of the second contact pads of second level package can be connecting through the second level conductive connecting through holes of second level package.

The present invention provides better reliability in TCT (temperature cycling test), drop test, ball shear test due to the properties of the core materials, isolating base and the CTE of core materials, isolating base (the preferred materials for the isolating base include PI or BT) is matching with CTE of print circuit board (PCB), furthermore, the build up layers with elastic/elongation property can absorb the thermal mechanical stress during temperature cycling.

Since the isolating mask (base) has fiber glass inside, the strength of isolating base (BT/FR5/FR4/PI . . . ) is great than the top dielectric layer, so, it can prevent the build up layers from being damaged during the external force, especially in package edge area. It is easy to replace the solder balls/bumps during rework process: the normal rework procedure of solder balls will not damage the top surface of package due to has isolating base.

Although preferred embodiments of the present invention has been described, it will be understood by those skilled in the art that the present invention should not be limited to the described preferred embodiment. Rather, various changes and modifications can be made within the spirit and scope of the present invention, as defined by the following claims.

Having described the invention, the following is claimed:

1. A package on package structure for semiconductor devices, comprising:
at least one first level package having at least one first level semiconductor die contained therein, wherein said package having first level contact pads formed on a first upper and lower surfaces of said first level package, said first level package having a first level upper build up layers and/or a first level lower build up layer to couple to the bonding pads of said first level semiconductor die and first level contact pads on said both upper and lower surfaces of said first level package; and
a second level package having at least one second level semiconductor die contained therein, wherein said second level package has a second level contact pads on a second upper and lower surfaces of said second level package, and second level conductive connecting through holes; wherein said second level package have a second level upper build up layer and/or second level lower build up layer to couple the bonding pads of second level semiconductor die to second level contact pads and said second level conductive connecting through holes on said upper and lower surface of said second level package, and the first level conductive through holes being coupled to said first level pads of upper and lower surfaces of said first level package and said second level pads of upper and lower surface of said second level package.

2. The structure of claim 1, wherein the dimension of said first level semiconductor package is identical to said second level semiconductor package.

3. The structure of claim 1, further comprising adhesion materials attached on lower surface of said first level package and the upper surface of said second level package.

4. The structure of claim 1, wherein the dimension of said first level semiconductor die is larger than the one of said second level semiconductor die.

5. The structure of claim 1, further comprising an isolation base formed over said first level package.

6. The structure of claim 4, wherein said isolation base is formed of epoxy, FR4, FR5, PI or BT, wherein said isolation base includes glass fiber contained therein.

7. The structure of claim 1, an air gap is created between said first level package and said second level package.

8. The structure of claim 1, further comprising at least one supporting structure between said first level package and said second level package.

9. The structure of claim 1, further comprising solder balls/bumps formed under said second level package.

10. The structure of claim 1, wherein the materials of said soldering balls/bumps include lead-free compositions.

11. The structure of claim 1, wherein the number of said conductive connecting through holes of said second level package are more than the one of said first level package.

12. The structure of claim 1, further comprising at least one passive component soldered on the upper build up layers of said first level package.

13. The structure of claim 1, wherein said first, second level upper and lower build up layers include multiple conductive lines.

14. The structure of claim 1, further comprising core paste formed adjacent to said first and second semiconductor die.

15. The structure of claim 1, further comprising dummy balls/bumps for mechanical supporting to avoid damage from external force.

16. A method of forming a package on package (PoP) structure for a semiconductor devices, comprising:
preparing a first level substrate having first die through holes window and a first conductive connecting through holes;
embedding said at least one first die into said first level die through holes window of said first level substrate by attaching materials in the surrounding gap and under said at least one first die;
forming first level build up layers on first upper and/or lower surfaces of said at least one first die and said first level substrate to couple first level bonding pads of said at least one first die to first solder metal pads of said first level build up layers through first level conductive connecting through holes;
preparing a second level substrate having a second level die through holes window and a second conductive connecting through holes;
embedding at least second die into said second level die through holes windows of said second level by attaching materials in the surrounding gap and under said at least one second die;
forming second level build up layers on second upper and/or lower surfaces of said second die and said second level substrate to couple second level bonding pads of said second die to second solder metal pads of said second level build up layers second level through conductive connecting through holes;
printing the soldering paste on said second solder metal pads of second upper surface of said second level package;
mounting said first lower surface of said first level package onto soldering pastes with fine alignment mounting system; and
re-flowing said soldering paste to form inter-connecting.

17. The method of claim 16, farther comprising a step of sawing panels from scribe lines to separate said “PoP” package.

18. The method of claim 16, further comprising forming RDL over said first and second level packages by laminated copper foil, sputtered metal, E-plated Cu/Ni/Au.

19. The method of claim 16, further comprising forming isolation base on said first level package and formed of epoxy, FR4, FR5, PI or BT.

20. The method of claim 17, wherein said isolation base includes glass fiber contained therein.

21. A method of forming a package on package (PoP) structure for a semiconductor devices, comprising:
preparing a first level substrate having first die through holes window, a first level contact metal pads on upper and lower surface;
embedding said at least one first die into said first level die through holes window of said first level substrate by attaching materials in the surrounding gap and under said at least one first die;
forming first level build up layers on first upper and/or lower surfaces of said at least one first die and said first level substrate to couple first level bonding pads of said at least one first die to first contact metal pads on first upper and lower surface of said first level substrate;
preparing a second level substrate having a second level die through holes window and a second conductive connecting through holes;
embedding at least second die into said second level die through holes windows of said second level by attaching materials in the surrounding gap and under said at least one second die;
forming second level build up layers on second upper and/or lower surfaces of said second die and said second level substrate to couple second level bonding pads of said second die to second contact metal pads of said second level build up layers and connecting a portion of said second contact metal pads on upper and lower surface of said second level substrate through said second level conductive connecting through holes; and
aligning and stacking said first and second level packages (panel form) by adhesion materials; mechanical drilling the inter-connecting through holes from the first contact metal pads of said first level package penetrate the upper surface, the core materials to the lower surface of said first level substrate and through the other portion of second contact pads of said second level package penetrate the upper surface, the core material to lower surface of said second level substrate; and filling the conductive materials to inter-connecting through holes to form inter-connecting.
